(19) United States
(12) Patent Application Publication
(10) Pub. No.: US 2026/0123151 A1
(43) Pub. Date: Apr. 30, 2026

(54) LED ARRAY WITH AIR-SPACED OPTICS

(71) Applicant: LUMILEDS LLC, San Jose, CA (US)

(72) Inventors: Grigoriy BASIN, San Jose, CA (US); Yu-Chen Shen, Sunnyvale, CA (US); Sudipta Romen Biswas, Santa Clara, CA (US)

(73) Assignee: LUMILEDS LLC, San Jose, CA (US)

(21) Appl. No.: 19/003,645

(22) Filed: Dec. 27, 2024

Related U.S. Application Data
(63) Continuation of application No. PCT/US2023/026329, filed on Jun. 27, 2023.
(60) Provisional application No. 63/357,620, filed on Jun. 30, 2022.

(51) Int. Cl. H10H 29/80; H01L 25/075; H10H 29/01; H10H 29/24; H10H 29/855

(52) U.S. Cl. CPC H10H 29/8421; H10H 29/034; H10H 29/24; H10H 29/855; H10H 29/882; H10W 90/00

(57) ABSTRACT

A light-emitting apparatus includes a light emitting device, a set of transmissive optical elements, and a side wall coating layer forming a rigid spacer. The set of optical elements is positioned with its back optics surface facing and spaced apart from the front device surface. Device output light emitted from light-emitting areas of the front device surface propagates to and through the optical elements. The space between the front device surface and the back optics surface, through which the device output light propagates, is either evacuated or filled with ambient air or inert gas. The side wall coating layer, on side surfaces of the light-emitting device or on side surfaces of multiple light-emitting elements thereof, extends beyond the front device surface to form the spacer, which leaves unobstructed at least portions of the one or more light-emitting areas of the front device surface.

### PRIORITY CLAIM

This application is a continuation of App. No. PCT/US2023/026329 entitled “LED array with air-spaced optics” filed 27 Jun. 2023 in the name of Basin et al, which claims priority of U.S. provisional App. No. 63/357,620 entitled “LED array with air-spaced optics” filed 30 Jun. 2022 in the name of Basin et al, both of said applications being incorporated herein by reference in their entireties.

### FIELD OF THE INVENTION

The invention relates generally to light emitting diodes and to phosphor-converted light emitting diodes.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths. In some instances the light emitted by the LED is used as the output of a device; such LEDs can be referred to as direct emitters.

In other instances LEDs can be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer.

Phosphor-converted LEDs may be designed so that all of the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED.

Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Multiple LEDs or pcLEDs can be formed together on a single substrate to form an array. Such arrays can be employed to form active illuminated displays, such as those employed in, e.g., smartphones and smart watches, computer or video displays, signage, or visualization systems (such as augmented- or virtual-reality displays), to form adaptive illumination sources, such as those employed in, e.g., automotive headlights, street lighting, camera flash sources, or flashlights (i.e., torches). An array having one or several or many individual devices per millimeter (e.g., device pitch or spacing of about a millimeter, a few hundred microns, or less than 100 microns, and separation between adjacent devices less than 100 microns or only a few tens of microns or less) typically is referred to as a miniLED array or a microLED array (alternatively, a μLED array). Such mini- or microLED arrays can in many instances also include phosphor converters as described above; such arrays can be referred to as pc-miniLED or pc-microLED arrays.

### SUMMARY

An inventive light-emitting apparatus comprises a light emitting device, a set of one or more transmissive optical elements, and a side wall coating layer that forms a substantially rigid spacer. The light-emitting device has a front device surface; the set of optical elements has front and back optics surfaces. The set of optical elements is positioned with its back optics surface facing and spaced apart from the front device surface. At least a portion of device output light emitted from one or more light-emitting areas of the front device surface propagates to and through the one or more optical elements. The space between the front device surface and the back optics surface, through which the device output light propagates, is either evacuated or filled with ambient air or inert gas. The side wall coating layer, on side surfaces of the light-emitting device or on side surfaces of multiple light-emitting elements thereof, extends beyond the front device surface to form the spacer, which leaves unobstructed at least portions of the one or more light-emitting areas of the front device surface.

Objects and advantages pertaining to LEDs, pcLEDs, miniLED arrays, pc-miniLED arrays, microLED arrays, and pc-microLED arrays may become apparent upon referring to the examples illustrated in the drawings and disclosed in the following written description or appended claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 shows a schematic cross-sectional view of an example pcLED.

FIGS. 2A and 2B show, respectively, cross-sectional and top schematic views of an example array of pcLEDs.

FIG. 3A shows a schematic cross-sectional view of an example array of pcLEDs arranged with respect to waveguides and a projection lens. FIG. 3B shows an arrangement similar to that of FIG. 3A, but without the waveguides.

FIG. 4A shows a top schematic view of an example miniLED or microLED array and an enlarged section of 3×3 LEDs of the array. FIG. 4B is a side cross-sectional schematic diagram of an example of a close-packed array of multi-colored phosphor-converted LEDS on a monolithic die and substrate.

FIG. 5A is a schematic top view of a portion of an example LED display in which each display pixel is a red, green, or blue phosphor-converted LED pixel. FIG. 5B is a schematic top view of a portion of an example LED display in which each display pixel includes multiple phosphor-converted LED pixels (red, green, and blue) integrated onto a single die that is bonded to a control circuit backplane.

FIG. 6A shows a schematic top view an example electronics board on which an array of pcLEDs may be mounted, and FIG. 6B similarly shows an example array of pcLEDs mounted on the electronic board of FIG. 6A.

FIGS. 7A-7D illustrate schematically construction of an example of a light-emitting apparatus.

FIGS. 8A-8D illustrate schematically construction of an example of a light-emitting apparatus.

FIGS. 9A-9C illustrate schematically construction of an example of a light-emitting apparatus.

FIGS. 10A-10C illustrate schematically construction of an example of a light-emitting apparatus.

FIGS. 11A-11G illustrate schematically an example of a process for constructing a light-emitting apparatus.

FIGS. 12A-12C are flow diagrams for examples of processes for constructing light-emitting apparatus.

FIG. 13 illustrates schematically an example of a light-emitting apparatus.

The examples depicted are shown only schematically; all features may not be shown in full detail or in proper proportion; for clarity certain features or structures may be exaggerated or diminished relative to others or omitted entirely; the drawings should not be regarded as being to scale unless explicitly indicated as being to scale. For example, individual LEDs may be exaggerated in their vertical dimensions or layer thicknesses relative to their lateral extent or relative to substrate or phosphor thicknesses. The examples shown should not be construed as limiting the scope of the present disclosure or appended claims.

### DETAILED DESCRIPTION

The following detailed description should be read with reference to the drawings, in which identical reference numbers refer to like elements throughout the different figures. The drawings, which are not necessarily to scale, depict selective examples and are not intended to limit the scope of the inventive subject matter. The detailed description illustrates by way of example, not by way of limitation, the principles of the inventive subject matter. For purposes of simplicity and clarity, detailed descriptions of well-known devices, circuits, and methods may be omitted so as not to obscure the description of the inventive subject matter with unnecessary detail.

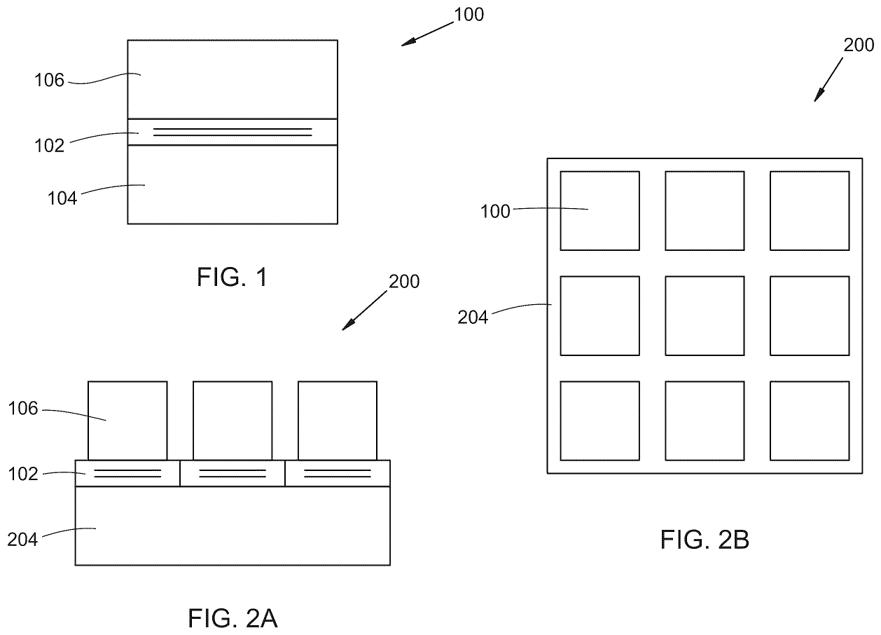

FIG. 1 shows an example of an individual pcLED 100 comprising a semiconductor diode structure 102 disposed on a substrate 104, together considered herein an “LED” or “semiconductor LED”, and a wavelength converting structure (e.g., phosphor layer) 106 disposed on the semiconductor LED. A direct-emitter LED would lack the wavelength converting structure 106. As employed hereinafter, the term “LED” shall refer generically to either or both direct-emitter LEDs and pcLEDs.

The semiconductor diode structure 102 typically comprises a junction or active region disposed between n-type and p-type layers. Application of a suitable forward bias across the diode structure 102 results in emission of light from the active region. The wavelength of the emitted light is determined by the composition and structure of the active region.

The LED may be, for example, a III-Nitride LED that emits blue, violet, or ultraviolet light. LEDs formed from any other suitable material system and that emit any other suitable wavelength of light may also be used. Other suitable material systems may include, for example, III-Phosphide materials, III-Arsenide materials, other binary, ternary, or quaternary alloys of gallium, aluminum, indium, nitrogen, phosphorus, arsenic, other III-V materials, or various II-VI materials.

Any suitable phosphor materials may be used for or incorporated into the wavelength converting structure 106, depending on the desired optical output from the pcLED.

FIGS. 2A-2B show, respectively, cross-sectional and top views of an array 200 of pcLEDs 100, each including a phosphor pixel 106, disposed on a substrate 204. Generally an array can include any suitable number of direct-emitter LEDs and/or pcLEDs arranged in any suitable manner. In the illustrated example the array is depicted as formed monolithically on a shared substrate, but alternatively an array can be formed from separate individual LEDs and/or pcLEDs (e.g., singulated devices that are assembled onto an array substrate). Individual phosphor pixels 106 are shown in the illustrated example, but alternatively a contiguous layer of phosphor material can be disposed across multiple LEDs 102. In some instances the array 200 can include light barriers (e.g., reflective, scattering, and/or absorbing) between adjacent LEDs 102, phosphor pixels 106, or both. Substrate 204 may optionally include electrical traces or interconnects, or CMOS or other circuitry for driving the LED, and may be formed from any suitable materials.

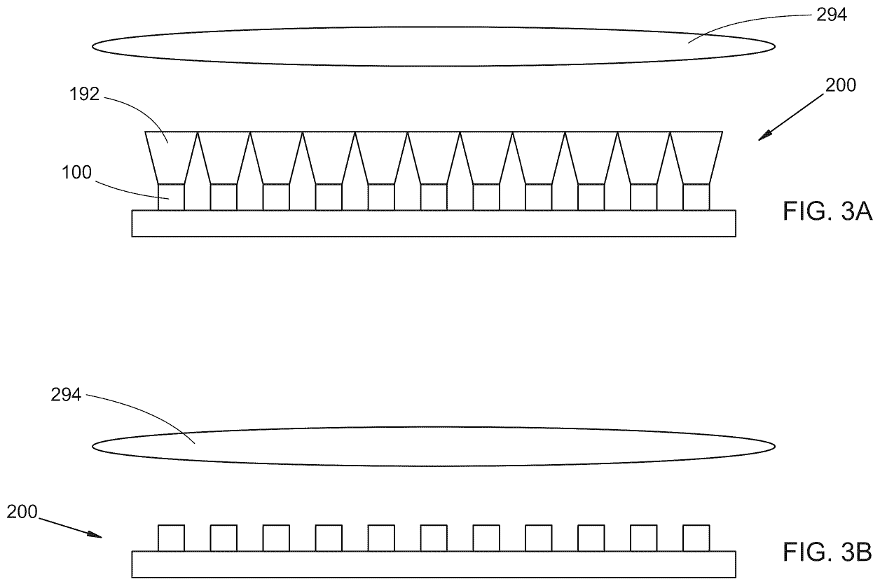

Individual LEDs and/or pcLEDs 100 may optionally incorporate or be arranged in combination with a lens or other optical element located adjacent to or disposed on the phosphor layer. Such an optical element, not shown in the figures, may be referred to as a “primary optical element” and may be of any suitable type of arrangement (e.g., conventional refractive or diffractive optical elements, or so-called nanostructured optical elements such as those disclosed in U.S. Pat. No. 11,327,283, U.S. Pub. No. 2020/0343416, U.S. Pub. No. 2020/0335661, U.S. Pub. No. 2021/0184081, U.S. Pub. No. 2022/0146079, or U.S. non-provisional application Ser. No. 17/825,143 filed May 26, 2022, each of which is incorporated by reference in its entirety). In addition, as shown in FIGS. 3A and 3B, an LED or pcLED array 200 (for example, mounted on an electronics board) can be arranged in combination with secondary optical elements such as waveguides, lenses, or both for use in an intended application (for the entire array, for subsets thereof, or for individual pixels; of any suitable type or arrangement, e.g., conventional refractive or diffractive optical elements, or so-called nanostructured optical elements, including any of those listed above). In FIG. 3A, light emitted by each LED or pcLED 100 of the array 200 is collected by a corresponding waveguide 192 and directed to a projection lens 294. Projection lens 294 may be a Fresnel lens, for example. This arrangement may be suitable for use, for example, in automobile headlights or other adaptive illumination sources. Other primary or secondary optical elements of any suitable type or arrangement can be included for each pixel, as needed or desired. In FIG. 3B, light emitted by LEDs and/or pcLEDs of the array 200 is collected directly by projection lens 294 without use of intervening waveguides. This arrangement may particularly be suitable when LEDs and/or pcLEDs can be spaced sufficiently close to each other, and may also be used in automobile headlights as well as in camera flash applications or other illumination sources. A miniLED or microLED display application may use similar optical arrangements to those depicted in FIGS. 3A and 3B, for example. Generally, any suitable arrangement of optical elements (primary, secondary, or both) can be used in combination with the LEDs or pcLEDs described herein, depending on the desired application.

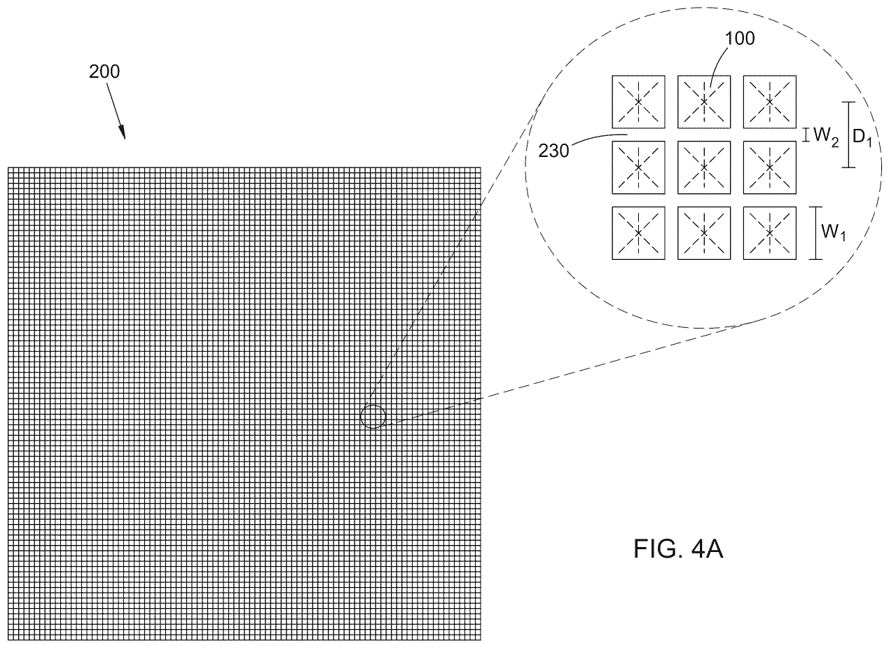

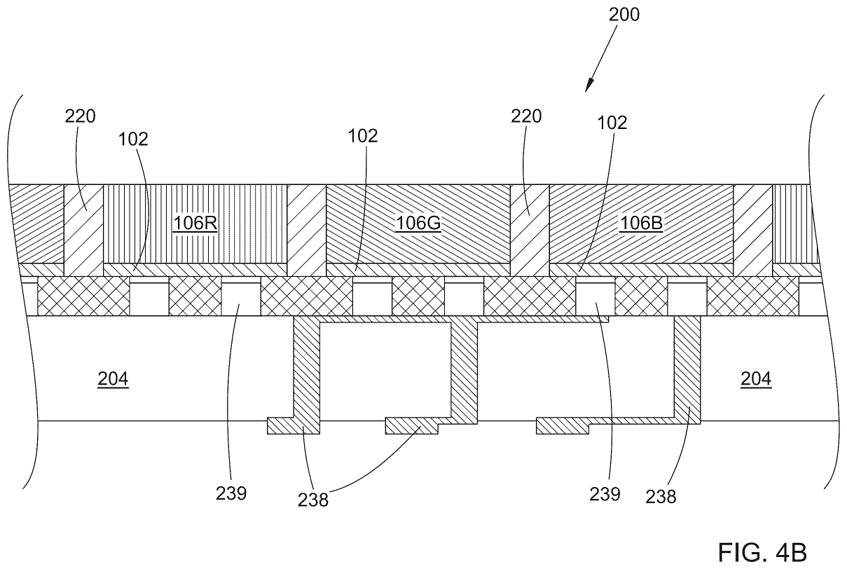

Although FIGS. 2A and 2B show a 3×3 array of nine pcLEDs, such arrays may include for example on the order of 101, 102, 103, 104, or more LEDs and or pcLEDs, e.g., as illustrated schematically in FIG. 4A. Individual LEDs 100 (i.e., pixels) may have widths w₁ (e.g., side lengths) in the plane of the array 200, for example, less than or equal to 1 millimeter (mm), less than or equal to 500 microns, less than or equal to 100 microns, or less than or equal to 50 microns. LEDs 100 in the array 200 may be spaced apart from each other by streets, lanes, or trenches 230 having a width w₂ in the plane of the array 200 of, for example, hundreds of microns, less than or equal to 100 microns, less than or equal to 50 microns, less than or equal to 20 microns, less than or equal to 10 microns, or less than or equal to 5 microns. The pixel pitch or spacing D₁ is the sum of w₁ and w₂. Although the illustrated examples show rectangular pixels arranged in a symmetric matrix, the pixels and the array may have any suitable shape or arrangement, whether symmetric or asymmetric. Multiple separate arrays of LEDs can be combined in any suitable arrangement in any applicable format to form a larger combined array or display.

LEDs having dimensions w₁ in the plane of the array (e.g., side lengths) of less than or equal to about 0.10 millimeters microns are typically referred to as microLEDs, and an array of such microLEDs may be referred to as a microLED array. LEDs having dimensions w₁ in the plane of the array (e.g., side lengths) of between about 0.10 millimeters and about 1.0 millimeters are typically referred to as miniLEDs, and an array of such miniLEDs may be referred to as a miniLED array.

An array of LEDs, miniLEDs, or microLEDs, or portions of such an array, may be formed as a segmented monolithic structure in which individual LED pixels are electrically isolated from each other, e.g., by trenches and/or insulating material. FIG. 4B is a schematic cross-sectional view of a close packed array 200 of multi-colored, phosphor converted LEDs 100 on a monolithic die and substrate 204. The side view shows GaN LEDs 102 attached to the substrate 204 through metal interconnects 239 (e.g., gold-gold interconnects or solder attached to copper micropillars) and metal interconnects 238. Phosphor pixels 106 are positioned on or over corresponding GaN LED pixels 102. The semiconductor LED pixels 102 or phosphor pixels 106 (often both) can be coated on their sides with a reflective mirror or diffusive scattering layer to form an optical isolation barrier 220 (which can in some instances also act as an electrical isolation barrier). In this example each phosphor pixel 106 absorbs light emitted by the LEDs 102 (e.g., UV light) and emits one of three different colors, e.g., red phosphor pixels 106R, green phosphor pixels 106G, and blue phosphor pixels 106B (still referred to generally or collectively as phosphor pixels 106). Such an arrangement can enable use of the LED array 200 as a color display. In an alternative arrangement (not shown), the LEDs can emit blue light, phosphors 106G and 106R can be employed to emit green and red output light, and the phosphor 106B can be omitted so that direct emission of some of the LEDs 102 provides blue output light. Many other arrangements employing any suitable or desirable numbers of LEDs or pcLEDs producing any suitable number and wavelengths of different colors can be employed.

The individual LEDs (pixels) in an LED array may be individually addressable, may be addressable as part of a group or subset of the pixels in the array, or may not be addressable. Thus, light emitting pixel arrays are useful for any application requiring or benefiting from fine-grained intensity, spatial, and temporal control of light distribution. These applications may include, but are not limited to, precise special patterning of emitted light from pixel blocks or individual pixels, in some instances including the formation of images as a display device. Depending on the application, emitted light may be spectrally distinct, adaptive over time, and/or environmentally responsive. The light emitting pixel arrays may provide preprogrammed light distribution in various intensity, spatial, or temporal patterns. The emitted light may be based at least in part on received sensor data and may be used for optical wireless communications. Associated electronics and optics may be distinct at a pixel, pixel block, or device level.

FIGS. 5A and 5B are examples of LED arrays 200 employed in display applications or visualization systems (e.g., augmented- or virtual-reality systems), wherein an LED display includes a multitude of display pixels. In some examples (e.g., as in FIG. 5A), each display pixel comprises a single semiconductor LED pixel 102 and a corresponding phosphor pixel 106R, 106G, or 106B of a single color (red, green, or blue). Each display pixel only provides one of the three colors. In some examples (e.g., as in FIG. 5B), each display pixel includes multiple semiconductor LED pixels 102 and multiple corresponding phosphor pixels 106 of multiple colors. In the example shown each display pixel includes a 3×3 array of semiconductor pixels 102; three of those LED pixels have red phosphor pixels 106R, three have green phosphor pixels 106G, and three have blue phosphor pixels 106B. Each display pixel can therefore produce any desired color combination. In the example shown the spatial arrangement of the different colored phosphor pixels 106 differs among the display pixels; in some examples (not shown) each display pixel can have the same arrangement of the different colored phosphor pixels 106. Any of the arrangements of FIGS. 5A and 5B can be adapted to include direct-emitting LEDs, instead of or in addition to pcLEDs.

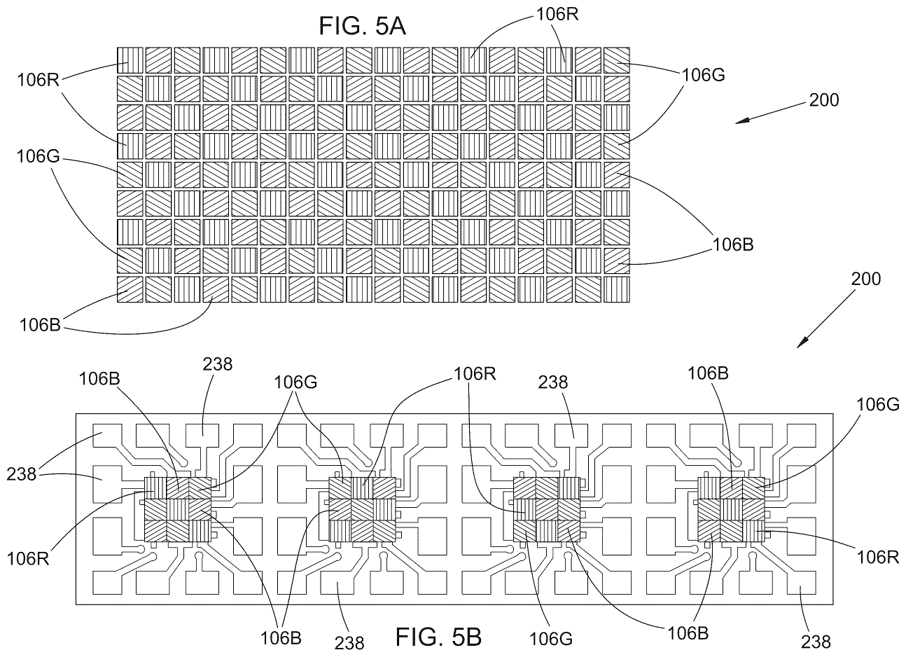

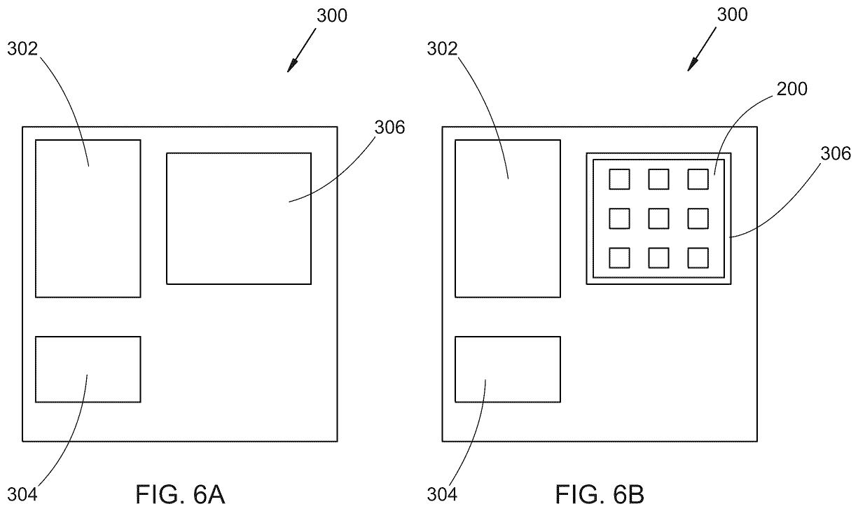

As shown in FIGS. 6A and 6B, a pcLED array 200 may be mounted on an electronics board 300 comprising a power and control module 302, a sensor module 304, and an LED attach region 306. Power and control module 302 may receive power and control signals from external sources and signals from sensor module 304, based on which power and control module 302 controls operation of the LEDs. Sensor module 304 may receive signals from any suitable sensors, for example from temperature or light sensors. Alternatively, pcLED array 200 may be mounted on a separate board (not shown) from the power and control module and the sensor module.

“Forward” and “backward” directions are generally perpendicular to the layers of the diode structure 102 and wavelength-converting layer 106; “lateral” directions are generally parallel to those layers. Designations of directions or surface as, e.g., “front” or “forward” versus “back”, “backward”, “rear”, or “rearward” are arbitrary but employed consistently only for convenience of description. For purposes of the present disclosure and appended claims, any arrangement of a layer, surface, substrate, diode structure, or other structure “on,” “over,” or “against” another such structure shall encompass arrangements with direct contact between the two structures as well as arrangements including some intervening structure between them. Conversely, any arrangement of a layer, surface, substrate, diode structure, or other structure “directly on,” “directly over,” or “directly against” another such structure shall encompass only arrangements with direct contact between the two structures. For purposes of the present disclosure and appended claims, a layer, structure, or material described as “transparent” and “substantially transparent” shall exhibit, at the nominal emission vacuum wavelength λ₀, a level of optical transmission that is sufficiently high, or a level of optical loss (due to absorption, scattering, or other loss mechanism) that is sufficiently low, that the light-emitting device can function within operationally acceptable parameters (e.g., output power or luminance, conversion or extraction efficiency, or other figures-of-merit including those described below).

For a variety of reasons it may be desirable to control or manipulate the far-field radiation pattern produced by a light source such as an LED, LED array, pcLED, or pcLED array. For example, redirecting LED output closer to normal to the emitting surface of the LED, luminance of the LED can be increased significantly. Optical elements (e.g., primary and/or secondary optics described above) can be placed on the light-emitting surface of the LED. In some examples the convergence, divergence, or collimation properties of the LED output light can be altered by focusing optical elements; in some examples the LED output light can be steered by steering optical elements. In some examples the optical elements can be refractive elements (e.g., lenses, microlenses, prisms, or microprisms); in some examples the optical elements can be nanostructured elements (e.g., including those described above and disclosed in the incorporated references). Especially for small or arrayed light sources, it is typically desirable to limit the thickness of the optical elements (e.g., less than 1.0 mm thick, less than 0.5 mm thick, or even thinner). The greater the refractive index contrast between the optical elements and the medium between the LED light-emitting surface and the optical elements, the thinner can be made the thickness of the optical elements.

Accordingly, it would be desirable to provide a medium with the smallest refractive index between the LED light-emitting surface and a set of optical elements used to manipulate the output light of the LED. The lowest refractive index (i.e., n=1.0) is achieved when that space is evacuated, or filled with ambient air or inert gas (e.g., nitrogen or noble gas). Examples of inventive light-emitting apparatus are disclosed herein that include a spacer to provide an evacuated, air-filled, or gas-filled space between the LED light-emitting surface and a set of one or more optical elements.

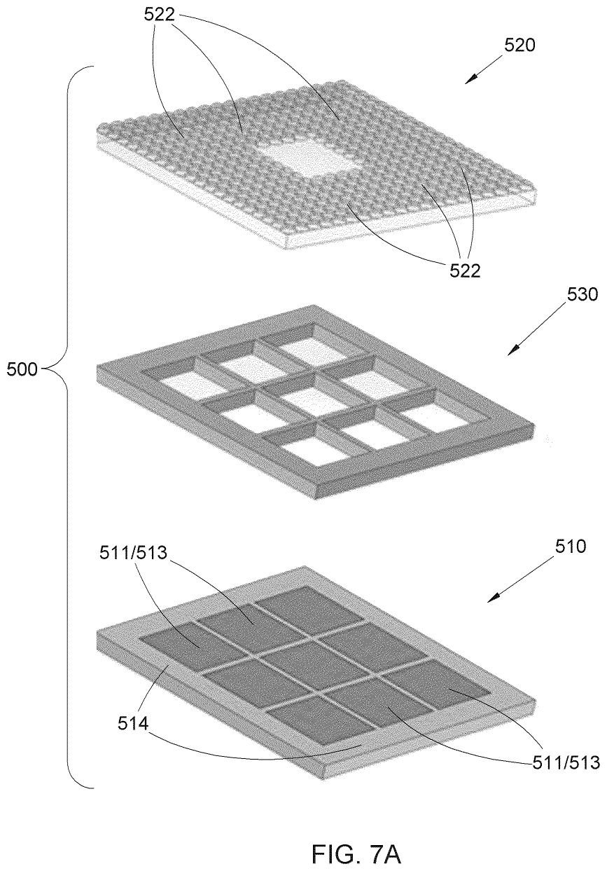

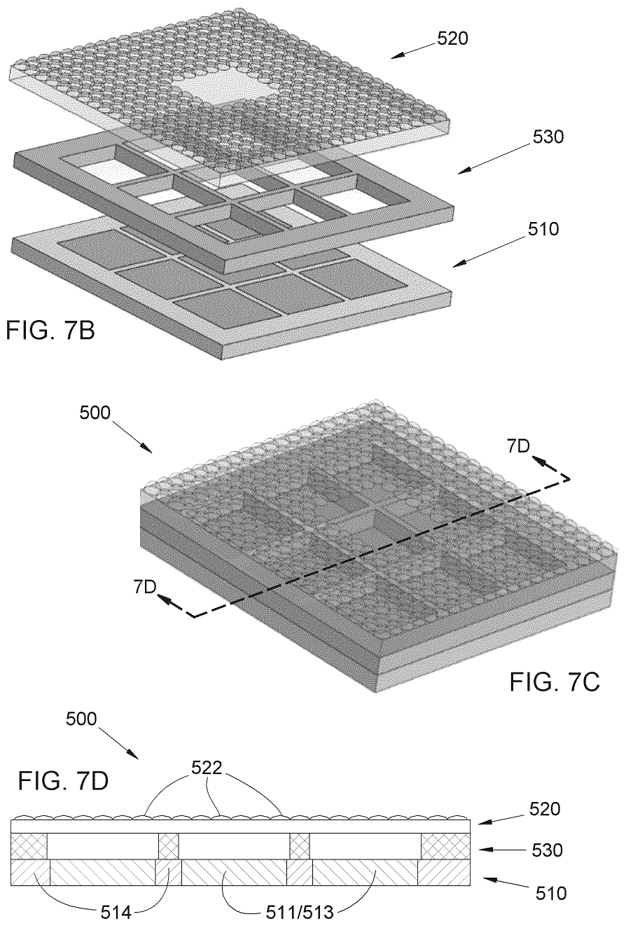

Examples of an inventive light-emitting apparatus 500 are illustrated schematically in FIGS. 7A-7D, 8A-8D, 9A-9C, and 10A-10C. A light-emitting device 510 has a front device surface, a set of one or more transmissive optical elements 520, and a substantially rigid spacer 530. The set of optical elements 520 has a front optics surface and a back optics surface, and is positioned with its back optics surface facing and spaced apart from the front device surface. At least a portion of device output light emitted from one or more light-emitting areas of the front device surface propagates to and through the one or more optical elements 520. The space between the front device surface and the back optics surface, through which the device output light propagates, is either evacuated or filled with ambient air or inert gas. The spacer 530 is positioned between and attached to the front device surface and the back optics surface, and is arranged to leave unobstructed at least portions of the one or more light-emitting areas of the front device surface.

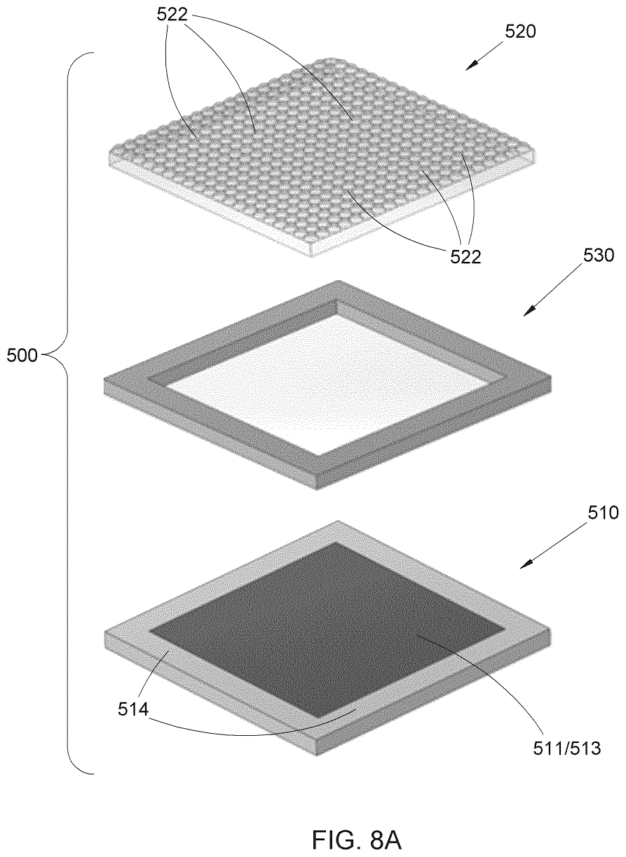

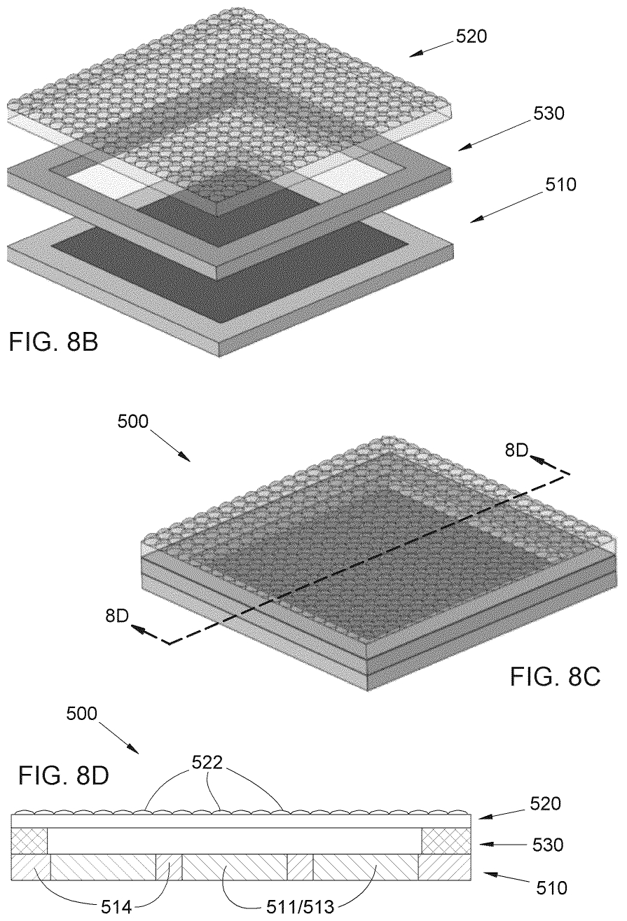

In some examples (e.g., as in FIGS. 8A-8D) the light-emitting device 510 can include only a single light-emitting element 511. In some examples (e.g., as in FIGS. 7A-7D, 9A-9C, and 10A-10C) the light-emitting device 510 can include an array of multiple light-emitting elements 511. In some examples the light-emitting elements 511 can be semiconductor light-emitting diodes (LEDs), each including a p-doped semiconductor layer, an n-doped semiconductor layer, and an active, light-emitting layer between them (e.g., one or more p-n junctions, one or more quantum wells, one or more multi-quantum wells, or one or more quantum dots). In some examples the LEDs 511 can include one or more materials among doped or undoped III-V, II-VI, or Group IV semiconductor materials, or alloys or mixtures thereof. The LEDs 511 can emit light at a nominal emission vacuum wavelength Ao, which in various examples can be greater than 0.20 μm, greater than 0.4 μm, greater than 0.8 μm, less than 10. μm, less than 2.5 μm, or less than 1.0 μm. In some examples the light emitted by the LED is the output light of the light-emitting device 510. In some examples, light emitted by the LED active layer is the entire light output of the device 510 (can be referred to as a direct emitter); in such instances the surface of the LED is the front device surface. In some examples the light-emitting device 510 can include one or more wavelength-conversion elements 513 (e.g., phosphors) arranged so as to absorb light at the nominal vacuum wavelength Ao and to emit light at a wavelength longer than Ao; in such examples the light output of the light-emitting device 510 includes light at the longer wavelength, alone or in combination with residual light at the wavelength Ao; in such instances the surface of the wavelength-conversion element 513, from which the light output emerges, is the front device surface.

In some examples wherein the light-emitting device 510 is an array of multiple light-emitting elements 511 (in some instances including a wavelength converters 513), those multiple light-emitting elements 511 can comprise discrete, structurally distinct elements assembled together to form the array. In some other examples wherein the light-emitting device 510 is an array of multiple light-emitting elements 511 (in some instances including a wavelength converters 513), those multiple light-emitting elements 511 can be integrally formed together on a common device substrate. In some examples nonzero spacing of the light-emitting elements 511 of the array can be less than 1.0 mm, less than 0.5 mm, less than 0.3 mm, less than 0.2 mm, less than 0.10 mm, less than 0.08 mm, less than 0.05 mm, less than 0.03 mm, less than 0.02 mm, or less than 0.010 mm. In some examples nonzero separation between adjacent light-emitting elements of the array being less than 50 μm, less than 20 μm, less than 10. μm, less than 5 μm, less than 2 μm, less than 1.0 μm, or less than 0.5 μm.

In some examples, the set of optical elements 520 can include only a single optical element 522. In some instances that single optical element 522 can transmit output of a single light-emitting element 511, while in other instances that single optical element 522 can transmit output of an array of multiple light-emitting elements 511 (e.g., similar to the arrangement of FIGS. 3A or 3B). In some examples the single optical element 522 can include a refractive focusing or steering optical element (e.g., a lens or a prism). In some examples the single optical element 522 can include a nanostructured focusing or steering optical element (e.g., a multitude of suitably sized and shaped projections, holes, depressions, inclusions, or structures, an array of single or double nano-antennae, a partial photonic bandgap structure, a photonic crystal, or an array of meta-atoms or meta-molecules; typically on a substrate; including those described above and disclosed in the incorporated references).

In some examples, the set of optical elements 520 can include an array of multiple optical elements 522 formed on or attached to a common substrate (e.g., as in FIGS. 7A-7D, 8A-8D, 9A-9C, or 10A-10C). In some examples all the optical elements 522 can be the same with respect to their optical properties (e.g., focal length or refracted angle); in other examples optical properties of at least some of the optical elements 522 can differ from those of other optical elements 522, and can vary with lateral position across the array 520. In some examples the array 520 of multiple optical elements 522 can include an array of refractive focusing or steering optical elements (e.g., microlenses or microprisms); in some examples the array 520 of multiple optical elements 522 can include an array of nanostructured focusing or steering optical elements (e.g., including those described above or in the incorporated references). The optical element set 520 can include any one or more suitable transparent materials (e.g., any one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped metal oxides, nitrides, or oxynitrides; one or more doped or undoped semiconductor oxides, nitrides, or oxynitrides; one or more optical glasses; or one or more doped or undoped polymers), and can be formed or fabricated in any suitable way (e.g., molding, stamping, self-assembly, lithography, and so forth).

In some examples the set 520 of optical elements 522 can have nonzero thickness less than 1.0 mm, less than 0.5 mm, less than 0.2 mm, less than 0.10 mm, less than 0.05 mm, less than 0.03 mm, less than 0.02 mm, or less than 0.01 mm. In some examples the thickness of the set 520 can include thickness of the optical elements 522 as well as a substrate that carries those optical elements (e.g., a silica or other transparent substrate on which are formed an array 520 of microlenses or microprisms or an array of nanostructured elements).

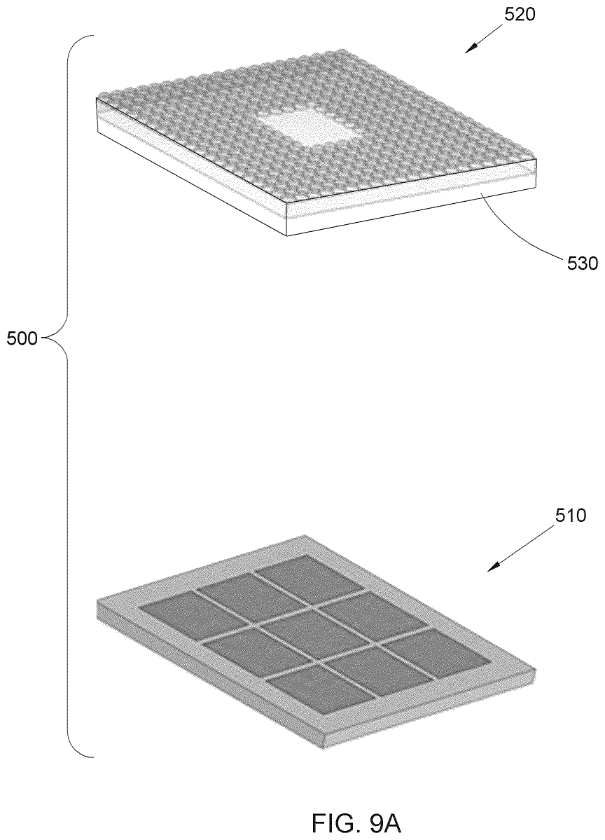

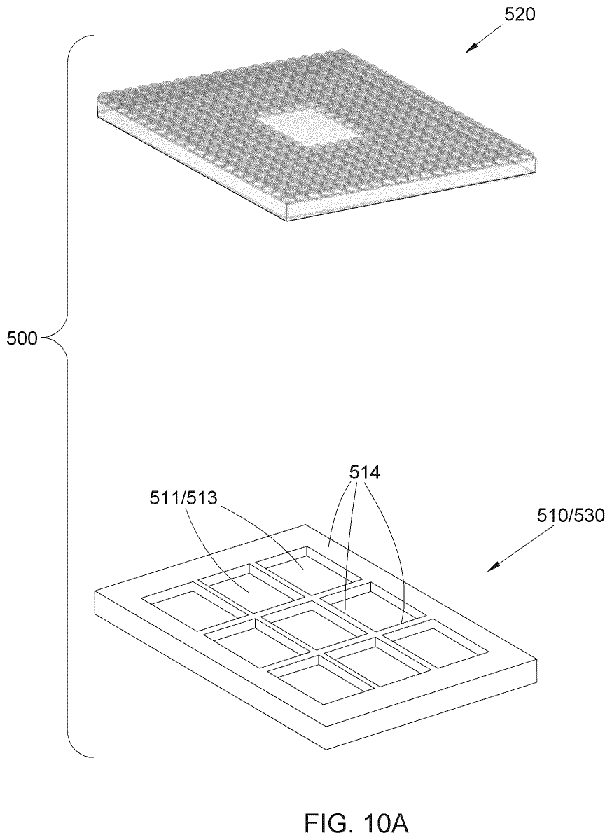

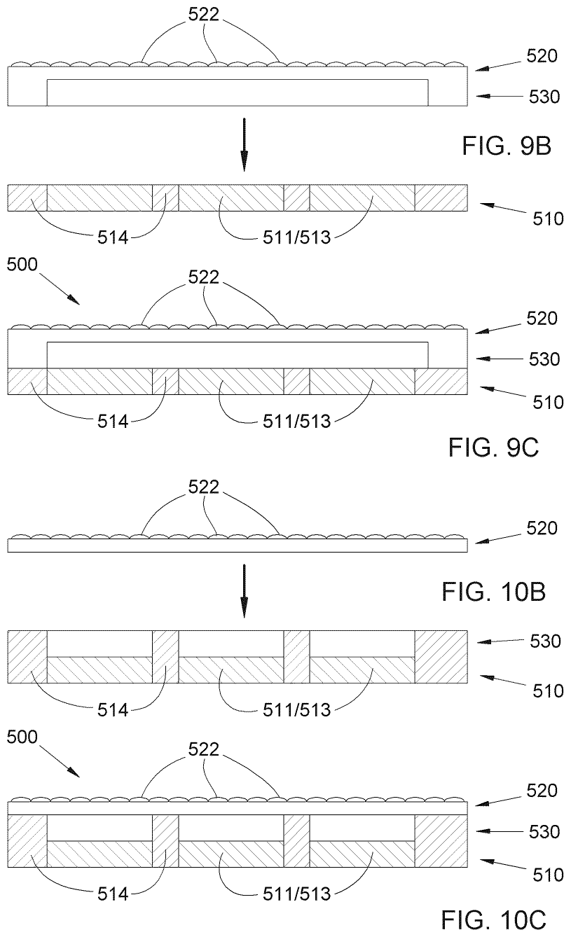

In some examples (e.g., as in FIGS. 8A-8D), an array 520 of multiple optical elements 522 can combined with a light-emitting device 510 that includes only a single light-emitting element 511 (in some instances including a wavelength-converter 513). In some examples (e.g., as in FIGS. 7A-7D, 9A-9C, or 10A-10C) an array 520 of multiple optical elements 522 can be combined with a light-emitting device 510 that includes an array of multiple light-emitting elements 511 (in some instances including wavelength converters 513). In various of those letter examples: (i) each optical element 522 of the array 520 can transmit light from a corresponding subset of multiple light-emitting elements 511, (ii) light from each light-emitting element 511 can be transmitted by a corresponding subset of multiple optical elements 522 of the array 520, or (iii) the multiple optical elements 522 of the array 520 can be arranged in a one-to-one correspondence with the multiple light-emitting elements 511 of the array 510, with each optical element 522 aligned with the corresponding light-emitting element 511.

In some examples, spacing between the front device surface and the back optics surface can be (i) greater than 1 μm, greater than 2 μm, greater than 5 μm, greater than 10 μm, greater than 20 μm, greater than 50 μm, greater than 100 μm, or greater than 200 μm, or (ii) less than 1 mm, less than 500 μm, less than 200 μm, or less than 100 μm. In some examples (e.g., as in FIGS. 8A-8D or 9A-9C), the spacer 530 can be arranged as a peripheral frame with only a single central opening therethrough. Such an arrangement can be suitable employed with a single light-emitting element 511, or with an array 510 of multiple light-emitting elements 511. In some examples (e.g., as in FIGS. 7A-7D or 10A-10C), the spacer 530 can be arranged as a peripheral frame with multiple cross members forming a grid that defines multiple openings through the spacer 530. Such an arrangement can be suitable employed with an array 510 of multiple light-emitting elements 511, typically with the cross members positioned above spaces or gaps between adjacent light-emitting elements 511. In some examples the one or more openings through the spacer 530 can have an optically reflective coating one the side surfaces of the opening(s). In some examples the spacer 530 can comprise one or more optically scattering materials or one or more optically reflective materials. In some examples the spacer 530 can include any one or more suitable materials (e.g., silica; sapphire; one or more metal or semiconductor oxides, nitrides, oxynitrides, carbides, or carbonates; one or more semiconductors or alloys or mixtures thereof; one or more polymers; or one or more metals or metallic alloys), or can include one or more of glassy or amorphous material, crystalline or polycrystalline material, or ceramic material. The spacer 530 can be formed or fabricated in any suitable way (e.g., molding, stamping, sintering, lithography, and so forth).

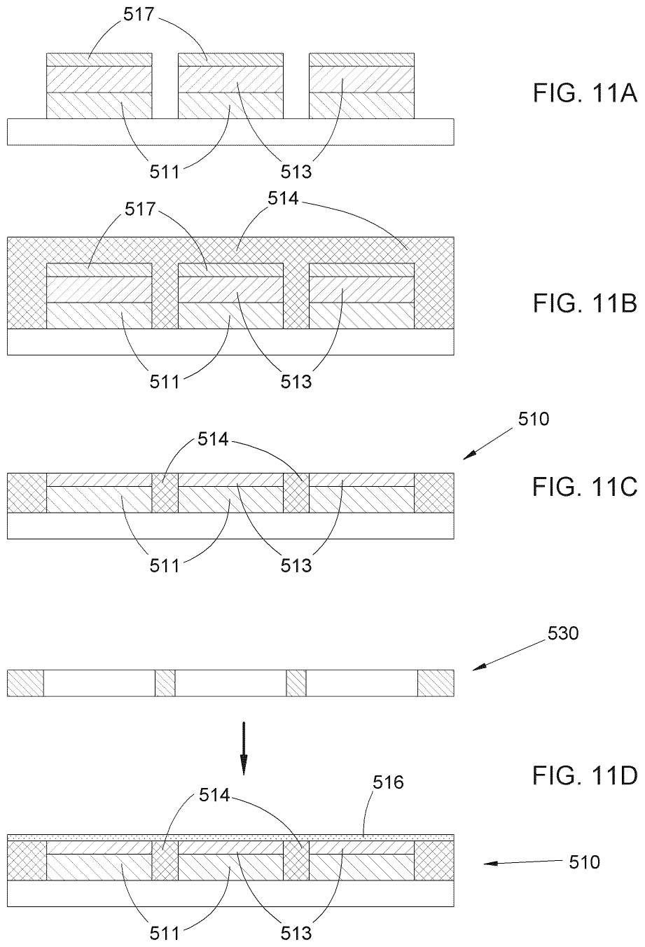

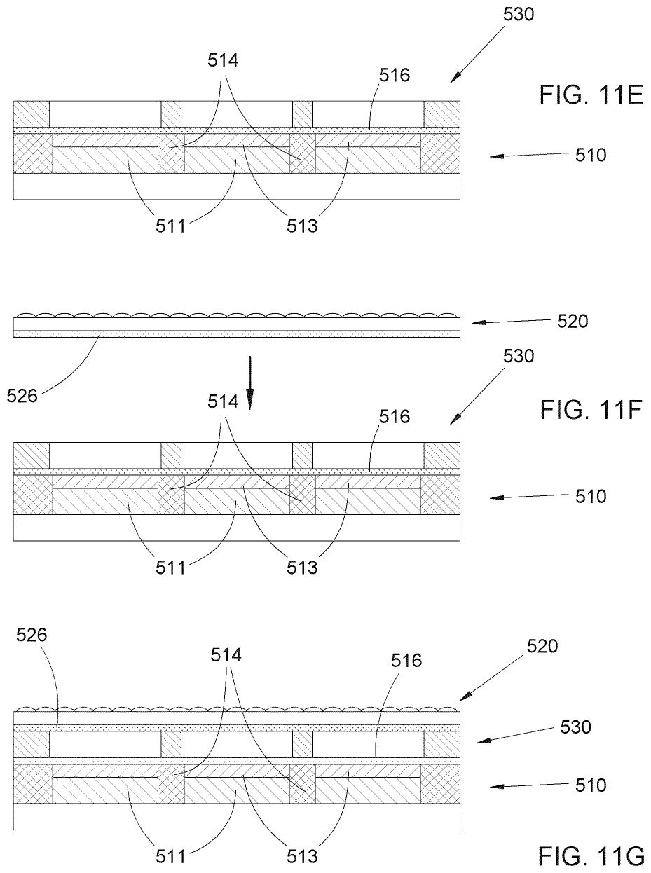

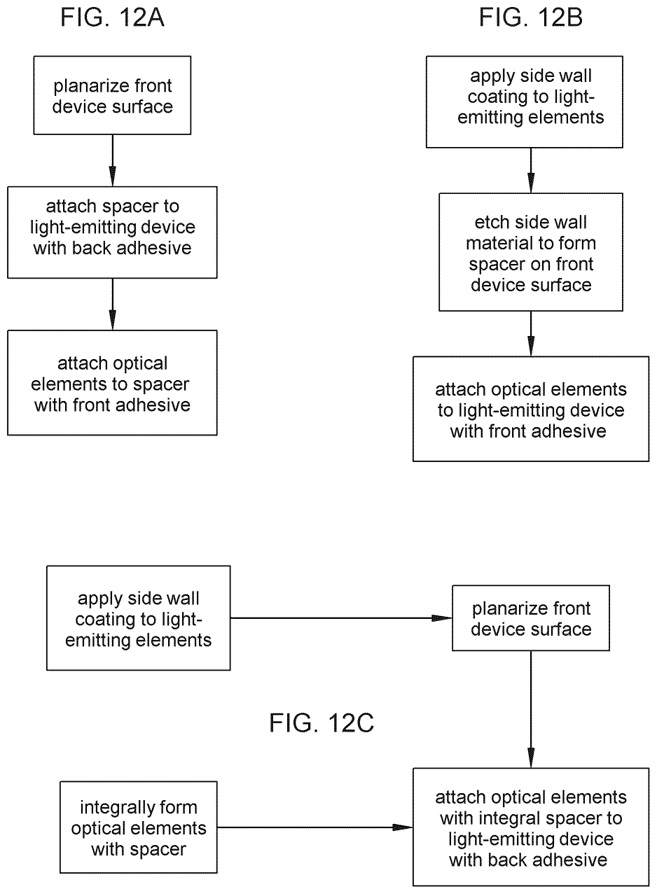

It would be desirable to reduce, minimize, or eliminate blockage by the spacer 530 of light emitted by the light-emitting device 510, i.e., to reduce, minimize, or eliminate the fraction of light-emitting area of the front device surface is covered by the spacer 530. Accordingly, in some examples the light-emitting device 510 can include a side wall coating layer 514 on side surfaces of the light-emitting device 510, and on side surfaces of the multiple light-emitting elements 511 of an array 510. Such side walls often can be employed for number of different reasons (e.g., for optical or electrical isolation of adjacent light-emitting elements, or for altering optical output of the light-emitting elements), and include any one or more suitable materials (e.g., one or more silicones or other polymers, one or more metals, one or more metal or semiconductor oxides such as titanium oxide, organic or inorganic pigments, and so forth) arranged in any suitable way (e.g., as scattering particles, pigments, absorbers, reflectors, gratings, nanostructured layers, and so forth). In some examples the front edges of the side wall coating layers 514 can be made coplanar with the front device surface, and the spacer 530 can be attached to the front edges of the side wall coating layers 514. Such a planarized surface of the side wall coating layers 514 provides a suitable mounting surface for attaching the spacer 530 to the light-emitting device 510, while reducing or avoiding blockage of light emitted by the device 510. In examples wherein the spacer 530 is arranged as a grid, the cross members of the spacer 530 can be positioned on and attached to the front edges of the side wall coating layers 514 between adjacent light-emitting elements 511. The side wall coating material 514 of any suitable type, composition, or arrangement (e.g., including those discussed above) can be deposited on and between the light-emitting elements 511 (e.g., as in FIGS. 11A-11G, 12A, and 12B); a suitable planarization process (e.g., chemical-mechanical polishing) can be employed to planarize the side wall material 514 and exposed the light-emitting device 511 (or wavelength converter 513) so that the front edges of the side wall coating 514 and the front device surface are coplanar. In some examples the light-emitting element 511 (or the wavelength converter 513) can include a sacrificial portion or layer 517 that is removed during the planarization process.

In some examples (e.g., as in FIGS. 7A-7D, 8A-8D, 11A-11G, or 12A) the spacer 530 can be attached to the light-emitting device 510 with a back adhesive layer 516 and attached to the one or more optical elements 520 with a front adhesive layer 526 (generally in no particular order; one order or the other might be preferred in specific instances). The adhesive layers 516 or 526 can be of any suitable type or composition (e.g., a silicone adhesive). The adhesive layers 516 and 526 can be the same adhesive in some examples, or can be different adhesives in other examples.

In some examples (e.g., as in FIGS. 9A-9C or 12C) the spacer 530 can be integrally formed with the optical elements 520 with the spacer 530 on the back optics surface and attached to the light-emitting device 510 with a back adhesive layer 516. The optical element set 520 and the spacer 530 can be fabricated in any suitable way, e.g., one or more of molding, stamping, sintering, self-assembly, lithography, and so forth. In some examples (e.g., as in FIGS. 10A-10C or 12B) the spacer 530 can be integrally formed on the front device surface of the light-emitting device 510 and attached to the back optics surface with a front adhesive layer 526. The light-emitting device 510 and the spacer 530 can be fabricated in any suitable way, e.g., molding, lithography, and so forth. In some examples, after depositing side wall coating material 514 on and between the light-emitting elements 511, instead of planarizing, the side wall coating material 514 can be patterned to expose light-emitting areas of the front device surface while leaving some of that material behind to form the spacer 530.

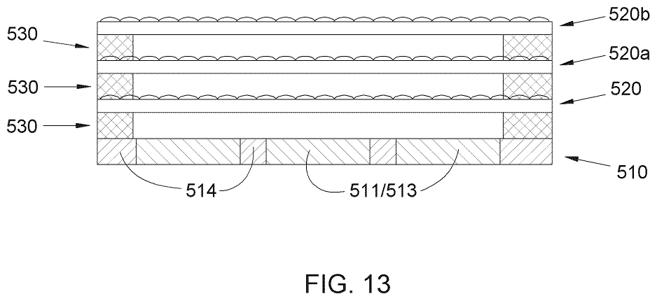

In some examples, the light-emitting apparatus 500 can include one or more additional sets 520a, 520b, etc of transmissive optical elements 522 (e.g., as in the example of FIG. 13). Each additional set has a corresponding front optics surface and a corresponding back optics surface. Each additional set can be positioned with its back optics surface facing and spaced apart from the front optics surface of an adjacent set of optical elements. At least a portion of device output light emitted from one or more light-emitting areas of the front device surface propagates to and through the one or more optical elements of each additional set. Space between each facing pair of front and back optics surfaces, through which the device output light propagates, can be either evacuated or filled with ambient air or inert gas. A corresponding substantially rigid additional spacer 530a, 530b, etc can be positioned between and attached to each facing pair of front and back optics surfaces. Each additional spacer can be arranged to leave unobstructed at least portions of the one or more light-emitting areas of the front device surface. Each additional spacer can be a separate, discrete component, or can be integrally formed on the front or back optics surfaces of one or more additional sets of optical elements.

In addition to the preceding, the following example embodiments fall within the scope of the present disclosure or appended claims:

Example 1. A light-emitting apparatus comprising: (a) a light-emitting device having a front device surface; (b) a set of one or more transmissive optical elements, the set having a front optics surface and a back optics surface and being positioned with the back optics surface facing and spaced apart from the front device surface, so that at least a portion of device output light emitted from one or more light-emitting areas of the front device surface propagates to and through the one or more optical elements, space between the front device surface and the back optics surface, through which the device output light propagates, being either evacuated or filled with ambient air or inert gas; and (c) a substantially rigid spacer positioned between and attached to the front device surface and the back optics surface, the spacer being arranged to leave unobstructed at least portions of the one or more light-emitting areas of the front device surface.

Example 2. The light-emitting apparatus of Example 1, spacing between the front device surface and the back optics surface being (i) greater than 1 μm, greater than 2 μm, greater than 5 μm, greater than 10 μm, greater than 20 μm, greater than 50 μm, greater than 100 μm, or greater than 200 μm, or (ii) less than 1 mm, less than 500 μm, less than 200 μm, or less than 100 μm.

Example 3. The light-emitting apparatus of any one of Examples 1 or 2, the set of optical elements having nonzero thickness less than 1.0 mm, less than 0.5 mm, less than 0.3 mm, less than 0.2 mm, less than 0.10 mm, less than 0.05 mm, less than 0.03 mm, less than 0.02 mm, or less than 0.01 mm.

Example 4. The light-emitting apparatus of any one of Examples 1 through 3, the spacer being arranged as a peripheral frame with only a single central opening therethrough.

Example 5. The light-emitting apparatus of any one of Examples 1 through 3, the spacer being arranged as a peripheral frame with multiple cross members forming a grid that defines multiple openings through the spacer.

Example 6. The light-emitting apparatus of any one of Examples 4 or 5, one or more openings through the spacer having on side surfaces thereof an optically reflective coating.

Example 7. The light-emitting apparatus of any one of Examples 1 through 6, the spacer including one or more materials among: silica; sapphire; one or more metal or semiconductor oxides, nitrides, oxynitrides, carbides, or carbonates; one or more semiconductors or alloys or mixtures thereof; one or more polymers; or one or more metals or metallic alloys.

Example 8. The light-emitting apparatus of any one of Examples 1 through 7, the spacer including one or more of glassy or amorphous material, crystalline or polycrystalline material, or ceramic material.

Example 9. The light-emitting apparatus of any one of Examples 1 through 8, the spacer comprising one or more optically scattering materials or one or more optically reflective materials.

Example 10. The light-emitting apparatus of any one of Examples 1 through 9, the one or more optical elements including only a single optical element.

Example 11. The light-emitting apparatus of Example 10, the single optical element including a refractive focusing or steering optical element.

Example 12. The light-emitting apparatus of any one of Examples 10 or 11, the single optical element including a nanostructured focusing or steering optical element.

Example 13. The light-emitting apparatus of any one of Examples 10 through 12, the light-emitting device including only a single light-emitting element.

Example 14. The light-emitting apparatus of any one of Examples 10 through 12, the light-emitting device including an array of multiple light-emitting elements.

Example 15. The light-emitting apparatus of any one of Examples 1 through 9, the one or more optical elements includes an array of multiple optical elements formed on or attached to a common substrate.

Example 16. The light-emitting apparatus of Example 15, one or more optical elements of the array differing from one or more other optical elements of the array with respect to respective optical properties thereof.

Example 17. The light-emitting apparatus of Example 15, the optical elements of the array all having substantially the same optical properties.

Example 18. The light-emitting apparatus of any one of Examples 15 through 17, the array of multiple optical elements including an array of refractive focusing or steering optical elements.

Example 19. The light-emitting apparatus of any one of Examples 15 through 18, the array of multiple optical elements including an array of nanostructured focusing or steering optical elements.

Example 20. The light-emitting apparatus of any one of Examples 15 through 19, the light-emitting device including only a single light-emitting element.

Example 21. The light-emitting apparatus of any one of Examples 15 through 19, the light-emitting device including an array of multiple light-emitting elements.

Example 22. The light-emitting apparatus of Example 21, each optical element of the array transmitting light from a corresponding subset of multiple light-emitting elements.

Example 23. The light-emitting apparatus of Example 21, light from each light-emitting element being transmitted by a corresponding subset of multiple optical elements of the array.

Example 24. The light-emitting apparatus of Example 21, the multiple optical elements being arranged in a one-to-one correspondence with the multiple light-emitting elements, and each optical element is aligned with the corresponding light-emitting element.

Example 25. The light-emitting apparatus of any one of Example 14 or Examples 21 through 24, the multiple light-emitting elements comprising discrete, structurally distinct light-emitting elements assembled together to form the array.

Example 26. The light-emitting apparatus of any one of Example 14 or Examples 21 through 24, the multiple light-emitting elements of the array being integrally formed together on a common device substrate.

Example 27. The light-emitting apparatus of any one of Example 14 or Examples 21 through 26, nonzero spacing of the light-emitting elements of the array being less than 1.0 mm, less than 0.5 mm, less than 0.3 mm, less than 0.2 mm, less than 0.10 mm, less than 0.08 mm, less than 0.05 mm, less than 0.03 mm, less than 0.02 mm, or less than 0.010 mm.

Example 28. The light-emitting apparatus of any one of Example 14 or Examples 21 through 27, nonzero separation between adjacent light-emitting elements of the array being less than 50 μm, less than 20 μm, less than 10. μm, less than 5 μm, less than 2 μm, less than 1.0 μm, or less than 0.5 μm.

Example 29. The light-emitting apparatus of any one of Examples 1 through 28, the light-emitting device including a side wall coating layer on side surfaces of the light-emitting elements, front edges of the side wall coating layers being coplanar with the front device surface, the spacer being attached to the front edges of the side wall coating layer.

Example 30. The light-emitting apparatus of any one of Examples 1 through 29, the light-emitting device including one or more semiconductor light-emitting diodes, each light-emitting diode including a p-doped semiconductor layer, an n-doped semiconductor layer, and an active, light-emitting layer between the p-doped and n-doped layers, each light-emitting diode being arranged for emitting light at a nominal emission vacuum wavelength λ₀.

Example 31. The light-emitting apparatus of Example 30, each one of the active layers including one or more p-n junctions, one or more quantum wells, one or more multi-quantum wells, or one or more quantum dots.

Example 32. The light-emitting apparatus of any one of Examples 30 or 31, the nominal emission vacuum wavelength Ao being greater than 0.20 μm, greater than 0.4 μm, greater than 0.8 μm, less than 10. μm, less than 2.5 μm, or less than 1.0 μm.

Example 33. The light-emitting apparatus of any one of Examples 30 through 32, the one or more light-emitting diodes including one or more materials among doped or undoped III-V, II-VI, or Group IV semiconductor materials, or alloys or mixtures thereof.

Example 34. The light-emitting apparatus of any one of Examples 30 through 33, the front device surface including one or more wavelength-conversion elements arranged so as to absorb light at the nominal vacuum wavelength Ao and to emit light at a wavelength longer than λο.

Example 35. The light-emitting apparatus of any one of Examples 1 through 34, the light-emitting device including a side wall coating layer on side surfaces of the light-emitting device, front edges of the side wall coating layers being coplanar with the front device surface, the spacer being attached to the front edges of the side wall coating layer.

Example 36. The light-emitting apparatus of any one of Examples 1 through 35 further comprising: (d) one or more additional sets of transmissive optical elements, each set having a corresponding front optics surface and a corresponding back optics surface and being positioned with the back optics surface facing and spaced apart from the front optics surface of an adjacent set of optical elements, so that at least a portion of device output light emitted from one or more light-emitting areas of the front device surface propagates to and through the one or more optical elements of each additional set, space between each facing pair of front and back optics surfaces, through which the device output light propagates, being either evacuated or filled with ambient air or inert gas; and (e) a corresponding substantially rigid additional spacer positioned between and attached to each facing pair of front and back optics surfaces, each additional spacer being arranged to leave unobstructed at least portions of the one or more light-emitting areas of the front device surface.

Example 37. The light-emitting apparatus of any one of Examples 1 through 36, the spacer being attached to the light-emitting device with a back adhesive layer and attached to the one or more optical elements with a front adhesive layer.

Example 38. A method for making the light-emitting apparatus of Example 37, the method comprising (A) attaching the spacer to the light-emitting device with the back adhesive layer, and (B) attaching the one or more optical elements to the spacer with the front adhesive layer.

Example 39. The light-emitting apparatus of any one of Examples 1 through 36, the spacer being integrally formed on the back optics surface and attached to the light-emitting device with a back adhesive layer.

Example 40. A method for making the light-emitting apparatus of Example 39, the method comprising (A) integrally forming the one or more optical elements and the spacer with the spacer on the back optics surface, and (B) attaching the spacer to the light-emitting device with the back adhesive layer.

Example 41. The method of Examples 38 or 40 further comprising, before attaching the spacer to the light-emitting device, (C) applying side wall coating material to side surfaces of the light-emitting device or to side surfaces of multiple light-emitting elements of the light-emitting device, and (D) planarizing the light-emitting device and the side wall coating material so that front edges of the side wall coating material are coplanar with the front device surface.

Example 42. The light-emitting apparatus of any one of Examples 1 through 36, the spacer being integrally formed on the front device surface and attached to the back optics surface with a front adhesive layer.

Example 43. A method for making the light-emitting apparatus of Example 42, the method comprising (A) integrally forming the light-emitting device and the spacer with the spacer on the front device surface, and (B) attaching the spacer to the one or more optical elements with the front adhesive layer.

This disclosure is illustrative and not limiting. Further modifications will be apparent to one skilled in the art in light of the present disclosure and are intended to fall within the scope of the present disclosure or appended claims. It is intended that equivalents of the disclosed example embodiments and methods, or modifications thereof, shall fall within the scope of the present disclosure or appended claims.

In the foregoing Detailed Description, various features may be grouped together in several example embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of a single disclosed example embodiment. Therefore, the present disclosure shall be construed as implicitly disclosing any embodiment having any suitable subset of one or more features-which features are shown, described, or claimed in the present application-including those subsets that may not be explicitly disclosed herein. A “suitable” subset of features includes only features that are neither incompatible nor mutually exclusive with respect to any other feature of that subset. Accordingly, the appended claims are hereby incorporated in their entirety into the Detailed Description, with each claim standing on its own as a separate disclosed embodiment. In addition, each of the appended dependent claims shall be interpreted, only for purposes of disclosure by said incorporation of the claims into the Detailed Description, as if written in multiple dependent form and dependent upon all preceding claims with which it is not inconsistent. It should be further noted that the cumulative scope of the appended claims can, but does not necessarily, encompass the whole of the subject matter disclosed in the present application.

The following interpretations shall apply for purposes of the present disclosure and appended claims. The words “comprising,” “including,” “having,” and variants thereof, wherever they appear, shall be construed as open ended terminology, with the same meaning as if a phrase such as “at least” were appended after each instance thereof, unless explicitly stated otherwise. The article “a” shall be interpreted as “one or more” unless “only one,” “a single,” or other similar limitation is stated explicitly or is implicit in the particular context; similarly, the article “the” shall be interpreted as “one or more of the” unless “only one of the,” “a single one of the,” or other similar limitation is stated explicitly or is implicit in the particular context. The conjunction “or” is to be construed inclusively unless: (i) it is explicitly stated otherwise, e.g., by use of “either . . . or,” “only one of,” or similar language; or (ii) two or more of the listed alternatives are understood or disclosed (implicitly or explicitly) to be incompatible or mutually exclusive within the particular context. In that latter case, “or” would be understood to encompass only those combinations involving non-mutually-exclusive alternatives. In one example, each of “a dog or a cat,” “one or more of a dog or a cat,” and “one or more dogs or cats” would be interpreted as one or more dogs without any cats, or one or more cats without any dogs, or one or more of each. In another example, each of “a dog, a cat, or a mouse,” “one or more of a dog, a cat, or a mouse,” and “one or more dogs, cats, or mice” would be interpreted as (i) one or more dogs without any cats or mice, (ii) one or more cats without any dogs or mice, (iii) one or more mice without any dogs or cats, (iv) one or more dogs and one or more cats without any mice, (v) one or more dogs and one or more mice without any cats, (vi) one or more cats and one or more mice without any dogs, or (vii) one or more dogs, one or more cats, and one or more mice. In another example, each of “two or more of a dog, a cat, or a mouse” or “two or more dogs, cats, or mice” would be interpreted as (i) one or more dogs and one or more cats without any mice, (ii) one or more dogs and one or more mice without any cats, (iii) one or more cats and one or more mice without any dogs, or (iv) one or more dogs, one or more cats, and one or more mice; “three or more,” “four or more,” and so on would be analogously interpreted.

For purposes of the present disclosure or appended claims, when a numerical quantity is recited (with or without terms such as “about,” “about equal to,” “substantially equal to,” “greater than about,” “less than about,” and so forth), standard conventions pertaining to measurement precision, rounding error, and significant digits shall apply, unless a differing interpretation is explicitly set forth. For null quantities described by phrases such as “substantially prevented,” “substantially absent,” “substantially eliminated,” “about equal to zero,” “negligible,” and so forth, each such phrase shall denote the case wherein the quantity in question has been reduced or diminished to such an extent that, for practical purposes in the context of the intended operation or use of the disclosed or claimed apparatus or method, the overall behavior or performance of the apparatus or method does not differ from that which would have occurred had the null quantity in fact been completely removed, exactly equal to zero, or otherwise exactly nulled.

For purposes of the present disclosure and appended claims, any labelling of elements, steps, limitations, or other portions of an embodiment, example, or claim (e.g., first, second, third, etc., (a), (b), (c), etc., or (i), (ii), (iii), etc.) is only for purposes of clarity, and shall not be construed as implying any sort of ordering or precedence of the portions so labelled. If any such ordering or precedence is intended, it will be explicitly recited in the embodiment, example, or claim or, in some instances, it will be implicit or inherent based on the specific content of the embodiment, example, or claim. In the appended claims, if the provisions of 35 USC § 112 (f) are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC § 112 (f) are not intended to be invoked for that claim.

If any one or more disclosures are incorporated herein by reference and such incorporated disclosures conflict in part or whole with, or differ in scope from, the present disclosure, then to the extent of conflict, broader disclosure, or broader definition of terms, the present disclosure controls. If such incorporated disclosures conflict in part or whole with one another, then to the extent of conflict, the later-dated disclosure controls.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

What is claimed is:

1. A light-emitting apparatus comprising:
a light-emitting device having a front device surface;
a side wall coating layer on side surfaces of the light-emitting device or on side surfaces of multiple light-emitting elements thereof, the side wall coating layer extending beyond the front device surface to form a substantially rigid spacer, the spacer being arranged to leave unobstructed at least portions of the one or more light-emitting areas of the front device surface; and
a set of one or more transmissive optical elements, the set having a front optics surface and a back optics surface and being positioned on the spacer and attached to front edges of the side wall coating layer with the back optics surface facing and spaced apart from the front device surface, so that at least a portion of device output light emitted from one or more light-emitting areas of the front device surface propagates to and through the one or more optical elements, space between the front device surface and the back optics surface, through which the device output light propagates, being either evacuated or filled with ambient air or inert gas.

2. The light-emitting apparatus of claim 1, spacing between the front device surface and the back optics surface being greater than 1.0 μm and less than 0.5 mm.

3. The light-emitting apparatus of claim 1, the set of optical elements having nonzero thickness less than 0.10 mm.

4. The light-emitting apparatus of claim 1, the spacer being arranged as a peripheral frame with only a single central opening therethrough.

5. The light-emitting apparatus of claim 1, the spacer being arranged as a peripheral frame with multiple cross members forming a grid that defines multiple openings through the spacer.

6. The light-emitting apparatus of claim 1, one or more openings through the spacer having on side surfaces thereof an optically reflective coating.

7. The light-emitting apparatus of claim 1, the spacer comprising one or more optically scattering materials or one or more optically reflective materials.

8. The light-emitting apparatus of claim 1, the one or more optical elements including only a single refractive or nanostructured focusing or steering optical element.

9. The light-emitting apparatus of claim 1, the one or more optical elements including an array of multiple refractive or nanostructured, focusing or steering optical elements formed on or attached to a common substrate.

10. The light-emitting apparatus of claim 9, one or more optical elements of the array differing from one or more other optical elements of the array with respect to respective optical properties thereof.

11. The light-emitting apparatus of claim 9 wherein the light-emitting device includes an array of multiple light-emitting elements, and (i) each optical element of the array transmits light from a corresponding subset of multiple light-emitting elements, or (ii) light from each light-emitting element is transmitted by a corresponding subset of multiple optical elements of the array.

12. The light-emitting apparatus of claim 9 wherein the light-emitting device includes an array of multiple light-emitting elements, and the multiple optical elements are arranged in a one-to-one correspondence with the multiple light-emitting elements, with each optical element aligned with the corresponding light-emitting element.

13. The light-emitting apparatus of claim 9 wherein the light-emitting device includes an array of multiple light-emitting elements, and (i) nonzero spacing of the light-emitting elements of the array is less than 1.0 mm, or (ii) nonzero separation between adjacent light-emitting elements of the array is less than 50 μm.

14. The light-emitting apparatus of claim 1, the light-emitting device including one or more direct-emitting or phosphor-converted semiconductor light-emitting diodes.

15. A method comprising:
(A) forming a side wall coating on side surfaces of a light-emitting device or on side surfaces of multiple light-emitting elements thereof, the side wall coating layer extending beyond a front device surface to form a substantially rigid spacer, the spacer being arranged to leave unobstructed at least portions of one or more light-emitting areas of the front device surface; and
(B) positioning on the spacer a set of one or more transmissive optical elements and attaching a back surface thereof to front edges of the side wall coating layer, with the back optics surface facing and spaced apart from the front device surface, so that at least a portion of device output light emitted from the one or more light-emitting areas of the front device surface propagates to and through the one or more optical elements, space between the front device surface and the back optics surface, through which the device output light propagates, being either evacuated or filled with ambient air or inert gas.

16. The method of claim 15 wherein part (B) includes attaching the one or more one or more optical elements to the front edges of the side wall coating layer with a front adhesive layer.

17. The method of claim 15 wherein part (A) includes first forming the side wall coating layer on the front device surface in addition to the side surfaces of the light-emitting device or on the side surfaces of multiple light-emitting elements thereof, and then spatially selectively removing portions of the side wall coating material so as to leave unobstructed at least portions of the one or more light-emitting areas of the front device surface.

18. The method of claim 15 wherein (i) spacing between the front device surface and the back optics surface is greater than 1.0 μm and less than 0.5 mm, or (ii) the set of optical elements has nonzero thickness less than 0.10 mm.

19. The method of claim 15, the spacer being arranged as a peripheral frame with only a single central opening therethrough.

20. The method of claim 15, the spacer being arranged as a peripheral frame with multiple cross members forming a grid that defines multiple openings through the spacer.
